(19) United States
(12) Patent Application Publication
(10) Pub. No.: US 2026/0082863 A1
(43) Pub. Date: Mar. 19, 2026

(54) SUBSTRATE TRANSFER APPARATUS

(71) Applicants: KAWASAKI JUKOGYO KABUSHIKI KAISHA, Kobe-shi (JP); Kawasaki Robotics (USA), INC., Wixom, MI (US)

(72) Inventors: Haruhiko TAN, Kobe-shi (JP); Weston WAHL, San Jose, CA (US); Justin LIU, Dallas, TX (US); Avish Ashok BHARWANI, Santa Clara, CA (US); Iori KURATA, San Jose, CA (US)

(73) Assignees: KAWASAKI JUKOGYO KABUSHIKI KAISHA, Kobe-shi (JP); Kawasaki Robotics (USA), INC., Wixom, MI (US)

(21) Appl. No.: 18/884,207

(22) Filed: Sep. 13, 2024

(51) Int. Cl. H01L 21/687; B65G 47/90; H01L 21/68

(52) U.S. Cl. CPC H10P 72/7602; B65G 47/90; H10P 72/50

(57) ABSTRACT

The substrate transfer apparatus according to one or more embodiments may include an end effector that includes a hand that grips a substrate; and a plunger that comes into contact with the substrate and performs alignment of the substrate including: a contact portion that comes into contact with the substrate; a shaft that moves the contact portion to contact the substrate; and an isolation wall that isolates an internal region from an outside, the internal region comprising a driver that drives the shaft, wherein the isolation wall comprises a shaft hole through which the shaft extends into the internal region, and the shaft comprises a cover in which a first end is connected to the shaft and a second end is connected to the isolation wall.

### BACKGROUND

The disclosure relates to a substrate transfer apparatus used in a working environment that is considered to affect the substrate transfer apparatus, such as under liquid, moisture, and dust.

A plurality of manufacturing apparatus is used when manufacturing semiconductor substrates, liquid crystal substrates, panels, and the like (hereinafter collectively referred to “substrates”). Transfer apparatus are used to transport the substrates between these manufacturing apparatus. The transfer apparatus include industrial robots.

Japan Patent Publication 2023-119658 (Kuribayashi) discloses a technology for reducing the amount of wear of sealing members to prevent liquid from entering the inside of the base of the hand in an industrial robot hand. Kuribayashi discloses that in a hand, a pushing member having a pushing part which contacts the end face of the conveyance object 2 and presses the end face of the conveyance object to the contacting surface of the end face contacting member is provided with a rotation shaft which is the rotation center of the pushing member and a first lever part that extends from the rotation shaft toward the outer side in the radial direction of the rotation shaft, and in the hand part, the pushing part is connected to the tip of the first lever part which is arranged outside the base of the hand.

### SUMMARY

A substrate transfer apparatus according to one or more embodiments may include an end effector, including a hand that grips the substrate; and a plunger that is in contact with the substrate and aligns the substrate including a contact portion that comes into contact with the substrate; a shaft that moves the contact portion to make contact with the substrate; and a side wall that isolates the internal region including the driver that drives the shaft from the outside. In one or more embodiments, the side wall may include a shaft hole through which the shaft extends into the internal region, and the shaft may include a cover in which the first end is connected to the shaft and the second end is connected to the side wall.

A substrate transfer apparatus according to one or more embodiments may include an end effector including a hand that grips the substrate; and a plunger that is in contact with the substrate and aligns the substrate including a contact portion that is in contact with the substrate; and an isolation wall that isolates the internal region including the driver that drives the shaft from the outside. In one or more embodiments, the isolation wall may include a shaft hole through which the contact portion extends into the internal region, and the contact portion may include a cover in which the first end is connected to the contact portion and the second end is connected to the isolation wall.

### BRIEF DESCRIPTION OF DRAWINGS

FIG. 1 is a diagram illustrating an upper surface of a substrate transfer apparatus according to one or more embodiments.

FIG. 2A is a diagram illustrating a perspective view of a portion of an end effector according to one or more embodiments.

FIG. 2B is a diagram illustrating a perspective cross-sectional view of a portion of an end effector according to one or more embodiments.

FIG. 3A is a diagram illustrating a perspective view of a plunger according to one or more embodiments.

FIG. 3B is a diagram illustrating an example of a cover.

FIG. 4 is a diagram illustrating a cross-sectional view of a plunger according to one or more embodiments.

FIG. 5 is a diagram illustrating a cross-sectional view of a plunger according to one or more embodiments.

FIG. 6 is a diagram illustrating a cross-sectional view of a plunger according to one or more embodiments.

### DETAILED DESCRIPTION

The substrate transfer apparatus according to one or more embodiments is described in detail with reference to the drawings. In the description of the drawings, identical or similar parts may be indicated by the same or similar numerals. The description in the drawing is schematic, and the relationship between thickness and dimensions, the ratio of the length and thickness of each part, etc. are examples, and do not limit the scope of technical concept. The dimensional relationships and dimension ratios may vary between drawings. In the following description, when explaining the positional relationship of each component, “top”, “bottom”, “right side”, “left side”, etc. are appropriately used based on the orientation of the drawing referenced and the specific object, but these indications do not limit the scope of technical ideas. Expressions such as “top”, “bottom”, “right side”, “left side”, etc. may be used even when each part is not contacted. “Longitudinal direction” may mean the direction of the long side on the main surface of the member. “Width direction” may mean the direction of the short side on the main surface of the member. “Height direction” or “vertical direction” may mean a direction related to the thickness of the main surface of the member. In addition, the X axis, the Y axis, the Z axis, or a combination thereof may be displayed in the figure, and “X axis direction”, “Y axis direction”, and “Z axis direction” may be used in the specification or drawing to describe the direction.

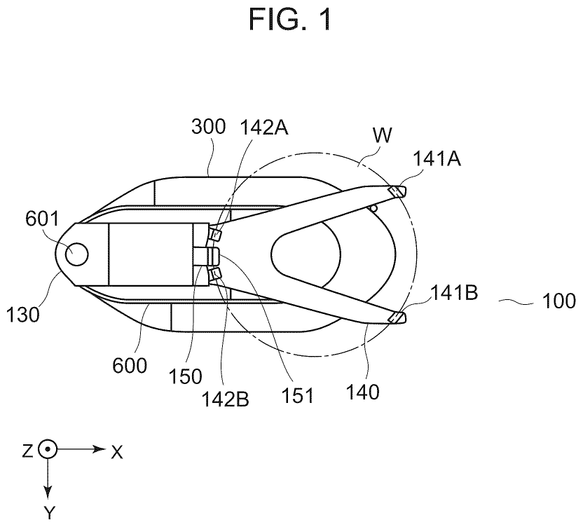

FIG. 1 is a diagram showing the upper surface of the substrate transfer apparatus 100 according to one or more embodiments. The substrate transfer apparatus 100 includes a base 300, a link 600 rotatably connected to the base 300, and an end effector 130 that is rotatably connected around the rotation shaft 601 and transports the substrate W. The substrate transfer apparatus 100 may include an extendable elevator (not shown) that may move the link 600 and the end effector 130 in the vertical direction (Z direction in the figure). Further, the substrate transfer apparatus 100 of FIG. 1 illustrates only one link 600, but is not limited to this, and may include two (2), three (3), four (4), and five (5) links 600. Further, the substrate transfer apparatus 100 may not include a link 600 and may directly connect the end effector 130 to an elevator (not shown). Further, the substrate transfer apparatus 100 may not include an elevator and may be directly connected with one or more links to the base 300. The substrate transfer apparatus 100 of FIG. 1 particularly indicates a horizontally articulated type substrate transfer apparatus, but is not limited to this, and a so-called direct-acting type substrate transfer apparatus that does not have a joint or a rotation mechanism may also be implemented. In the substrate transfer apparatus 100, various operations are controlled by a controller (not shown). The controller performs various operation controls including lifting and lowering operations and rotation operations of the elevator, link 600, and end effector 130 etc.

The end effector 130 includes a hand 140 that grips substrates such as semiconductor substrates and liquid crystal substrates, and various panels (hereinafter collectively referred to as simply the substrate W), and a plunger 150 that grips and aligns the substrate in contact with the substrate W. The Hand 140 includes substrate contact portions 141A, 141B, 142A, and 142B. The plunger 150 includes a contact portion 151 that may be moved to grip the substrate W. Under the control of the controller, the end effector 130 acquires the substrate W from a predetermined position using the hand 140 and transports the substrate W to the predetermined position. When acquiring the substrate W stored in the FOUP (Front Opening Unified Pod) or the like, the hand 140 enters the upper or lower part of the substrate W, and when it is recognized that the hand 140 has entered to a predetermined position on the substrate W, the entering of the hand 140 is stopped. Thereafter, a gripping operation of the substrate W is performed. At this time, the contact portion 151 of the plunger 150 moves and grips the substrate W. As a method by which the hand 140 grips the substrate W, a so-called edge grip method may be used. In the edge grip method, the substrate W is held to some extent by the substrate contact portions 141A, 141B, 142A, and 142B, and the contact portion 151 is moved to contact the substrate W. Thereby, the contact portion 151 grips the substrate W. Further, as another method by which the hand 140 grips the substrate W, a vacuum adsorption type may be used. For example, a vacuum unit (not shown) is provided at each of the substrate contact portions 141A, 141B, 142A, and 142B. After moving the contact portion 151 to contact with the substrate W, the vacuum portion is brought into close proximity or contact from the upper or lower part of the substrate W, and the substrate W is adsorbed by applying negative pressure to the vacuum unit. Thereby, the end effector 130 may grip and transport the substrate W to a predetermined position.

The substrate W includes a substrate such as a semiconductor substrate and a liquid crystal substrate and various panels. For example, the substrate W shown in FIG. 1 is circular but is not limited thereto. The substrate W may be a transparent material containing a material that transmits light, or may be translucent, or non-transparent.

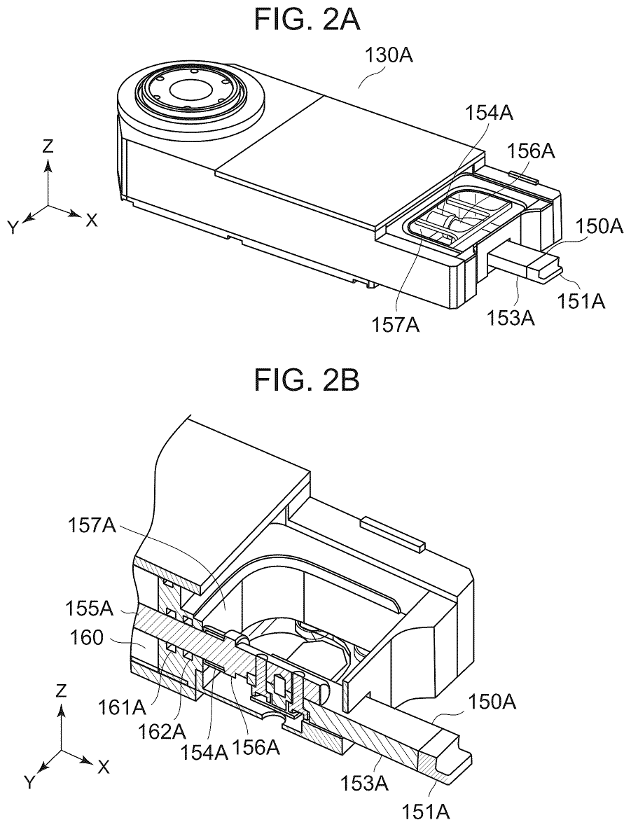

FIG. 2A is a perspective view illustrating a portion of an end effector 130A according to one or more embodiments. FIG. 2B is a perspective cross-sectional view illustrating a portion of the end effector 130A according to one or more embodiments. In FIGS. 2A and 2B, the hand 140 is omitted for convenience of explanation. The end effector 130A includes a plunger 150A. The plunger 150A includes a contact portion 151A that comes into contact with a substrate (not shown) and secures the substrate, and a holder 153A that holds the contact portion 151A and makes the contact portion 151A movable. The holder 153A is connected to the shaft 155A. The shaft 155A is connected to the holder 153A at the first end, and the second end is extended to the internal region 160 through a shaft hole provided in the isolation wall 157A, and is connected to the driver (not shown). By applying driving power to the shaft 155A, the shaft 155A performs reciprocating motion in the longitudinal direction (X direction shown) of the shaft 155A, for example. The holder 153A also moves back and forth with the reciprocating movement of the shaft 155A. With the reciprocating movement of the holder 153A, the contact portion 151A moves and comes into contact with the substrate to secures the substrate. The shaft 155A includes a cover 154A covering at least a part of the shaft 155A, and a connector 156A connected to the cover 154A.

The cover 154A is connected to the connector156A at the first end and the second end is connected to the isolation wall 157A. The connector 156A has a convex portion protruding from the shaft 155A, and the first end of the cover 154A is connected to the side of the connector 156A. Since the first end of the cover 154A is connected to the connector 156A, the cover 154A moves along with the reciprocating motion of the shaft 155A. Thus, the cover 154A may be extendable. The isolation wall 157A is a wall provided for isolating the internal region 160 from the outside. Since the drive of the driver may be transmitted to the contact portion 151A, the shaft 155A and the contact portion 151A may be directly connected. In other words, the holder 153A is not always necessary. Further, since the drive of the driver may be transmitted to the contact portion 151A, the contact portion 151A may be connected to the driver. In other words, the shaft 155A is not always necessary. When the contact portion 151A is directly connected to the driver, the connector 156A connected to the cover 154A may be provided in the contact portion 151A. In this case, the cover 154A is connected to a connector 156A provided in the contact portion 151A at the first end, and the second end is connected to the isolation wall 157A.

The connection between the covers 154A and 156A and the connection between the cover 154A and the isolation wall 157A may be connected inside of the cover 154A so as to prevent the intrusion of the external environment.

Specifically, connection is made to seal the inside of the cover 154A from an external environment that may contain liquids, moisture, dust, and the like. It may be sealed and connected so that the external environment does not enter the inside of the cover 154A. The connection between the cover 154A and the connector 156A, and the connection between the cover 154A and the isolation wall 157A may be screwed connections in that they are highly reliable. In this case, a plate (not shown) is provided between the cover 154A and the connector 156A, the cover 154A and the isolation wall 157A, and the cover 154A and the connector 156A, and the cover 154A and the isolation wall 157A may be connected via the plate. Further, the connection between the cover 154A and the connector 156A, and the connection between the cover 154A and the isolation wall 157A may be connected by an adhesive in that they are easy to install. Further, in terms of ease of replacement, a groove may be formed on the connector 156A and the isolation wall 157A, and the connection may be such that the cover 154A is fitted. Furthermore, the connection between the cover 154A and the connector 156A, and the connection between the cover 154A and the isolation wall 157A may be made to seal the connector using other components.

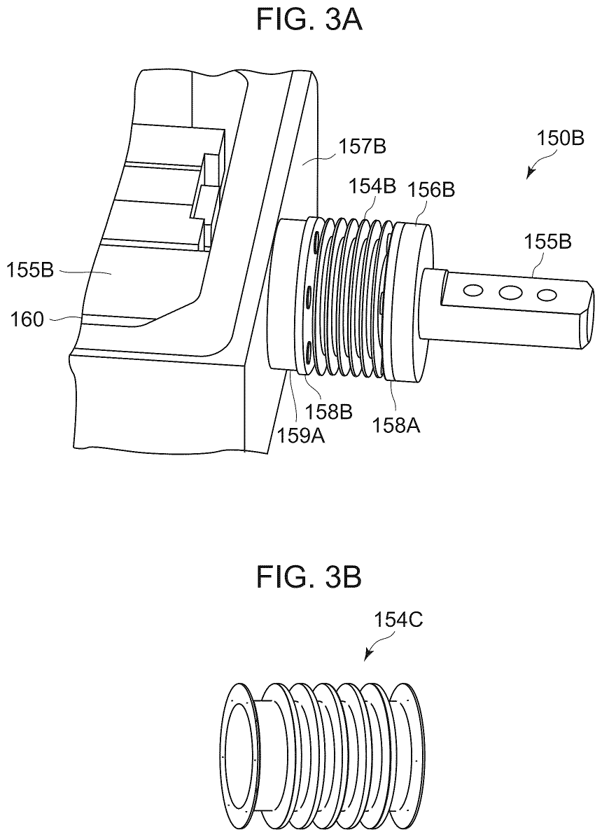

FIG. 3A is a perspective view illustrating a plunger 150B according to one or more embodiments. The plunger 150B has a shaft 155B including a connector 156B. The cover 154B is connected to the connector 156B at the first end, and the second end is connected to the connector 159A of the isolation wall 157B. The connector 156B has a convex portion protruding from the shaft 155B, and the first end of the cover 154B is connected to the side of the connector 156B. The isolation wall 157B is a wall provided for sealing the internal region 160 from the outside, and includes a connector 159A. The connector 159A has a shape protruding from the isolation wall 157B, and the second end of the cover 154B is connected to the protruding surface of the connector 159A.

The connection between the cover 154B and the connector 156B and the connection between the cover 154B and the connector 159A are connected so as to prevent intrusion into the inside of the cover 154B from the external environment. Specifically, connections are made to seal the inside of the cover 154B from an external environment that may contain liquids, moisture, dust, and the like. In FIG. 3A, the connection between the cover 154B and the connector 156B, and the connection between the cover 154B and the connector 159A may be made by screwing in terms of high reliability. In this case, a plate 158A may be provided in the connection between the cover 154B and the connector 156B, and the cover 154B may be sandwiched between the plate 158A and the connector 156B and screwed together. Similarly, a plate 158A may be provided in the connection between the cover 154B and the connector 156B, and the cover 154B may be sandwiched between the plate 158A and the connector 156B and screwed together. Similarly, a plate 158B may be provided in the connection between the cover 154B and the connector 159A, and the cover 154B may be sandwiched between the plate 158B and the connector 159A and screwed. The shaft 155B may generate vibration because, for example, reciprocating motion in the longitudinal direction (X direction shown) of the shaft 155B. By providing the plates 158A and 158B, it may be possible not only to prevent intrusion into the inside of the cover 154B from the external environment, but also to alleviate the loosening of the screw due to vibration. Further, the connection between the cover 154B and the connector 156B, and the connection between the cover 154B and the connector 159A may be connected by an adhesive in terms of ease of installation. Further, in terms of ease of replacement, a groove may be formed in the connector 156B and the connector 159A, and the connection may be such that the cover 154B is fitted into the groove. Furthermore, the connection between the cover 154B and the connector 156B and the connection between the cover 154B and the connector 159A may be sealed using other components.

By connecting the cover 154B and the connector 156B, and by connecting the cover 154B and the connector 159A, the entry of liquid, dust, etc. into the cover 154B from the external environment is prevented. The isolation wall 157B is provided with a shaft hole for extending the shaft 155B to the internal region 160. For this reason, there is a possibility that a liquid or the like may enter the internal region 160 from the external environment through the shaft hole. In the internal region 160, devices that may be affected by the external environment may be arranged, such as a driver that drives the shaft 155B, various sensors, air cylinders, or semiconductor substrates. According to the substrate transfer apparatus according to one or more embodiments, the influence of liquid or the like from the external environment may be reduced through the shaft hole, and various devices in the internal region 160 may be protected.

In the plunger 150B shown in FIG. 3A, a cover 154B is connected to the connector 159A of the isolation wall 157B and the connector 156B having a convex portion. By connecting the cover 154B to the convex portion of the connector 156B, a space is created between the shaft 155B and the cover 154B. For this reason, it may have unexpected results from the prior art of reducing friction between the shaft 155B and the cover 154B. In Kuribayashi, the sealing member is isolated in close contact with the outer peripheral surface of the rotating shaft. In this case, prevention of intrusion of liquid, dust, or the like from the external environment to the inside may be reduced, and friction between the sealing member and the rotating shaft may occur. In the substrate transfer apparatus according to one or more embodiments, it may be possible to improve the prevention of intrusion of liquids, dust, etc. from the external environment to the inside, and to minimize the friction at the shaft 155B. Thus, the substrate transfer apparatus according to one or more embodiments may have unexpected results.

FIG. 3B is a diagram illustrating an example of the cover 154C. The cover 154C has an accordion structure in which the mountain fold and the valley fold are alternately repeated in the central part. When the shaft 155B performs reciprocating motion, the cover 154C expands and contracts. Thereby, since the inside of the cover 154C may be sealed from the external environment even if the shaft 155B performs reciprocating motion, the influence from the external environment may be reduced, and the device stored in the internal region 160 may be protected. In addition, the accordion structure is thin and compact when folded, reducing interference with other devices. In order to reduce the influence of the external environment in the internal region 160, the cover 154C may be arranged to cover the periphery of the shaft 155B from the convex portion of the connector 156B to the isolation wall 157B. The cover 154C shown in FIG. 3B is cylindrical, but is not necessarily limited to a cylindrical shape as long as it covers the periphery of the shaft 155B, and may be, for example, a square shape.

Here, it may be preferrable that the accordion structure of the cover 154C adjusts the width of the mountain fold and the valley fold so as not to interfere with the shaft 155B when expanding and contracting. Further, the longitudinal length of the cover 154C may be determined based on the width of the reciprocating motion of the shaft 155B. The longitudinal length of the cover 154C is preferably within a range that does not interfere with the reciprocating movement of the shaft 155B. For example, it may be preferrable that the longitudinal length of the cover 154C is equal to or greater than the distance between the connector 156B and the connector 159A when the connector 156B is closest to the internal region 160. Furthermore, it may be preferrable that the longitudinal length of the cover 154C is equal to or greater than the distance between the connector 156B and the connector 159A when the shaft 155B may be farthest away from the internal region 160. For example, when the reciprocating movement width of the shaft 155B is 10 mm, the longitudinal length of the cover 154C may be between 5 mm and 50 mm, and the longitudinal length of the cover 154C may be preferable between 7 mm and 25 mm.

The cover 154C may use a material that expands and contracts. If the cover 154C expands within a range that does not interfere with the reciprocating movement of the shaft 155B, it may not be necessary to have an accordion structure. Rubber such as fluorine rubber, chloroprene (CR) rubber and silicon rubber may be preferable as a material of the cover 154C because of their excellent heat resistance, oil resistance, weather resistance, and corrosion resistance. When there is a significant air pressure difference between the external environment and the internal region 160, or in an environment where the external environment is vacuum, it may be preferrable the material of the cover 154C is made of metal for sealing.

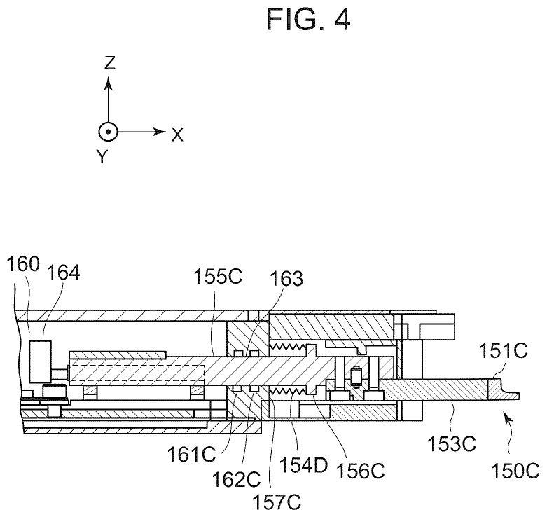

FIG. 4 is a cross-sectional view illustrating the plunger 150C according to one or more embodiments. The plunger 150C includes a contact portion 151C that comes into contact with a substrate (not shown) and secures the substrate, and a holder 153C that holds the contact portion 151C and makes the contact portion 151C movable. The holder 153C is connected to the shaft 155C. The shaft 155C is connected to the holder 153C at the first end, and the second end extends to the internal region 160 through the shaft hole and is connected to the driver (not shown). The driver provides driving power to the shaft 155C, and the shaft 155C performs reciprocating motion in the longitudinal direction of the shaft 155C, for example. The holder 153C also moves with the movement of the shaft 155C. With the movement of the holder 153C, the contact portion 151C moves and secures the substrate in contact with the substrate. The shaft 155C includes a cover 154D covering at least a portion of the shaft 155C, and a connector 156C connected to the cover 154D. The cover 154D is connected to the connector 156C at the first end and the second end is connected to the isolation wall 157C. The connector 156C has a convex portion protruding from the shaft 155C, and the first end of the cover 154D is connected to the side of the connector 156B. The isolation wall 157C is a wall provided for isolating the internal region 160 from the outside. The isolation wall 157C is provided with a shaft hole 163 for extending the shaft 155C to the internal region 160. In the internal region 160, an internal device 164 that may be affected by the external environment may be arranged, such as a driver that drives the shaft 155C, various sensors, air cylinders, or semiconductor substrates. According to the substrate transfer apparatus according to one or more embodiments, the influence of liquid or the like from the external environment may be reduced through the shaft hole, and various devices in the internal region 160 may be protected.

In the plunger 150C shown in FIG. 4, sealing members 161C and 162C are included inside the isolation wall 157C, but when the cover 154D is less likely to be affected by the external environment, the plunger 150C may not include the sealing members 161C and 162C.

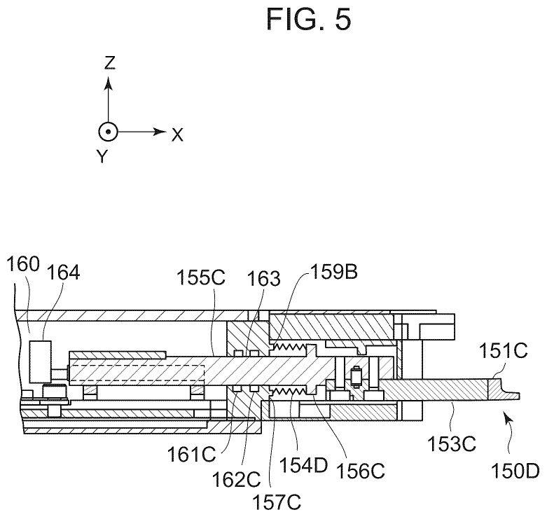

FIG. 5 is a cross-sectional view illustrating a plunger 150D according to one or more embodiments. The plunger 150D includes a contact portion 151C that comes into contact with a substrate (not shown) and secures the substrate, and a holder 153C that holds the contact portion 151C and makes the contact portion 151C movable. The holder 153C is connected to the shaft 155C. The shaft 155C is connected to the holder 153C at the first end, and the second end extends to the internal region 160 through the shaft hole and is connected to the driver (not shown). The driver provides driving power to the shaft 155C, and the shaft 155C performs reciprocating motion in the longitudinal direction of the shaft 155C, for example. The holder 153C also moves with the movement of the shaft 155C. With the movement of the holder 153C, the contact portion 151C moves and secures the substrate in contact with the substrate. The shaft 155C includes a cover 154D covering at least a portion of the shaft 155C, and a connector 156C connected to the cover 154D. Here, in the plunger 150D, the cover 154D is connected to the connector 156C at the first end, and the second end is connected to the connector 159B of the isolation wall 157C. The connector 159B has a shape protruding from the isolation wall 157C and has a shape that protrudes in a convex shape in the direction approaching the cover 154D (X-axis direction). In FIG. 5, the side surfaces and upper surfaces of the connector 159B have a planar shape, but are not limited thereto, and may be curved. In particular, when the shaft 155C is cylindrical or the shaft hole 163 is circular, the connector 159B may have a circular protruding shape to surround the shaft hole 163. The connector 159B has a convex portion protruding from the shaft 155C, and the first end of the cover 154D is connected to the side of the connector 156B. The isolation wall 157C is a wall provided for isolating the internal region 160 from the outside. The isolation wall 157C is provided with a shaft hole 163 for extending the shaft 155C to the internal region 160. In the internal region 160, an internal device 164 that may be affected by the external environment may be arranged, such as a driver that drives the shaft 155C, various sensors, air cylinders, or semiconductor substrates. According to the substrate transfer apparatus according to one or more embodiments, the influence of liquids and the like from the external environment may be reduced through the shaft hole 163 to protect various devices in the internal region 160.

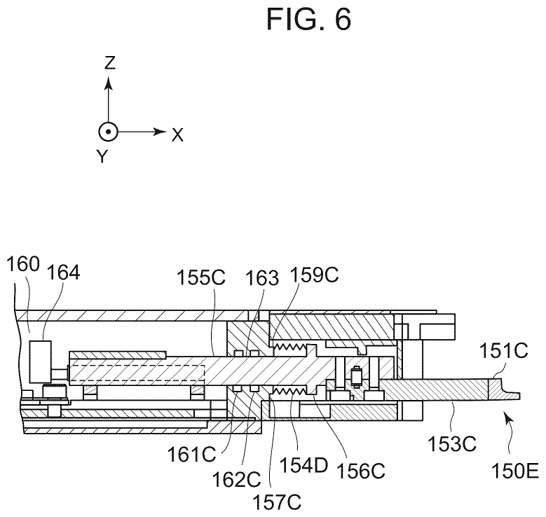

FIG. 6 is a cross-sectional view illustrating a plunger 150E according to one or more embodiments. In the plunger 150E, the cover 154D is connected to the connector 156C at the first end, and the second end is connected to the connector 159C of the isolation wall 157C. The connector 159C has a shape protruding from the isolation wall 157C and has a shape protruding in the direction approaching the cover 154D (X-axis direction). In FIG. 6, the side surfaces and upper surfaces of the connector 159C have a planar shape, but are not limited thereto, and may be curved. In particular, when the shaft 155C is cylindrical or the shaft hole 163 is circular, the connector 159C may have a circular protruding shape to surround the shaft hole 163. Here, the side surface of the connector 159C has a shape in contact with the shaft 155C. That is, a part of the side surface of the connector 159C is arranged without a difference in level with the surface of the shaft hole 163. In the internal region 160, an internal device 164 that may be affected by the external environment may be arranged, such as a driver that drives the shaft 155C, various sensors, air cylinders, or semiconductor substrates. According to the substrate transfer apparatus according to one or more embodiments, the influence of liquids and the like from the external environment may be reduced through the shaft hole 163 to protect various devices in the internal region 160. Further, since the side surface of the connector 159C has a shape in contact with the shaft 155C, the thickness of the shaft hole 163 increases. For this reason, the influence from the external environment that the internal device 164 receives may be further reduced.

As described above, one or more embodiments have been described. In the semiconductor manufacturing process, there are various processes that use liquids, such as wet etching, wafer cleaning process, photoresist-related process, and CMP (Chemical Mechanical Polishing) process. In addition, in the semiconductor manufacturing process, there are various processes that generate dust, such as etching process, film formation process, photolithography process, dicing process, etc. The substrate transfer apparatus may be used in these external environments, but in the substrate transfer apparatus, a device that may be affected by the external environment may be placed, such as a driver, various sensors, an air cylinder, or a semiconductor substrate. When these devices are used in the external environment as described above, they may cause failure or malfunction. In the substrate transfer apparatus according to one or more embodiments, since the internal region in which the above-described apparatus is stored may be isolated from the external environment, failure or malfunction of the apparatus provided in the substrate transfer apparatus may be reduced. Therefore, the reliability of the substrate transfer apparatus may be improved.

One or more embodiments described above herein may be combined with each other as far as practicable within the scope of the intended embodiment. The above examples are exemplary in all respects and should be considered not limiting. The illustrated and described embodiments may be extended to include other embodiments in addition to those specifically delivered, without departing from the technical scope. The technical scope should be determined not only by the foregoing description, but also in the light of the specification containing equivalents. Thus, all configurations, including the technical and equal ranges, are intended to be included in the technical range.

1. A substrate transfer apparatus comprising:
an end effector comprising:
a hand that grips a substrate; and
a plunger that comes into contact with the substrate and performs alignment of the substrate comprising:
a contact portion that comes into contact with the substrate;
a shaft that moves the contact portion to contact the substrate; and
an isolation wall that isolates an internal region from an outside, the internal region comprising a driver that drives the shaft, wherein
the isolation wall comprises a shaft hole through which the shaft extends into the internal region, and
the shaft comprises a cover in which a first end is connected to the shaft and a second end is connected to the isolation wall.

2. The substrate transfer apparatus according to claim 1, wherein
the shaft comprises a convex portion protruding from the shaft.

3. The substrate transfer apparatus according to claim 2, wherein
the cover is connected to the convex portion.

4. The substrate transfer apparatus according to claim 3, wherein
the cover comprises a plate that sandwiches the cover with the convex portion, and the plate is connected to the convex portion.

5. The substrate transfer apparatus according to claim 1, wherein
the cover comprises a material that expands and contracts.

6. The substrate transfer apparatus according to claim 1, wherein
the cover has an accordion structure.

7. The substrate transfer apparatus according to claim 6, wherein
there is a space between the cover and the shaft.

8. The substrate transfer apparatus according to claim 1, wherein
the cover has a cylindrical shape and covers a periphery of the shaft from a convex portion to the isolation wall.

9. The substrate transfer apparatus according to claim 1, wherein
the cover is connected to the shaft at the first end sealed from an external environment, and the second end is connected to the isolation wall sealed from the external environment.

10. The substrate transfer apparatus according to claim 1, wherein
the driver that drives the shaft is arranged in the internal region.

11. The substrate transfer apparatus according to claim 10, wherein
a sensor is arranged in the internal region.

12. The substrate transfer apparatus according to claim 1, wherein
the substrate transfer apparatus is used in a process using a liquid.

13. A substrate transfer apparatus comprising:
an end effector comprising:
a hand gripping a substrate; and
a plunger that comes into contact with the substrate and performs alignment of the substrate comprising:
a contact portion that comes into contact with the substrate; and
an isolation wall that isolates an internal region from an outside, the internal region comprising a driver that drives a shaft, wherein
the isolation wall comprises a shaft hole through which the contact portion extends into the internal region, and
the contact portion comprises a cover in which a first end is connected to the contact portion and a second end is connected to the isolation wall.
